(19) United States
(12) Patent Application Publication
(10) Pub. No.: US 2010/0007245 A1
(43) Pub. Date: Jan. 14, 2010

(54) Electroactive Polymer Actuators, Applications and Methods for Fabrication Thereof

(76) Inventors: Edwin Jager, Linkoping (SE); Magnus Krogh, Ljungsbro (SE)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/223,674

(22) PCT Filed: Feb. 7, 2007
(86) PCT No.: PCT/EP2007/001030

§ 371 Date: Aug. 24, 2009

Related U.S. Application Data
(60) Provisional application No. 60/765,745, filed on Feb. 7, 2006.

(30) Foreign Application Priority Data
Feb. 7, 2006 (SE) 0600261-2

(51) Int. Cl. H02N 2/04; H01L 41/193

(52) U.S. Cl. 310/330

(57) ABSTRACT

In one embodiment, an actuator device includes a first electroactive polymer layer, including an active electroactive polymer layer portion. In one embodiment, the active electroactive polymer layer portion is controllably shiftable between a substantially neutral state and a buckled state.

### TECHNICAL FIELD

The disclosure relates to an actuator device comprising an electroactive polymer layer, and different embodiments thereof.

The disclosure further relates to applications of such actuator devices, and to methods for fabrication of such actuator devices.

### BACKGROUND

Electroactive polymers (EAP) are a novel class of materials that have electrically controllable properties. An overview on electroactive polymers can be found in “Electroactive Polymers (EAP) Actuators as Artificial Muscles—Reality, Potential, and Challenges” 2^{nd} ed. Y. Bar-Cohen (ed.) ISBN 0-8194-5297-1.

One class of EAPs are conducting polymers. These are polymers with a backbone of alternating single and double bonds. These materials are semiconductors and their conductivity can be altered from insulating to conducting with conductivities approaching those of metals. Polypyrrole (PPy) is one such conducting polymer and will be taken here as an example.

PPy can be electrochemically synthesized from a solution of pyrrole monomers and a salt as is know to those skilled in the art. After synthesis, PPy is in its oxidized, or also called doped, state. The polymer is doped with an anion A−.

PPy can be electrochemically oxidized and reduced by applying the appropriate potential to the material. This oxidation and reduction is accompanied with the transport of ions and solvents into and out of the conducting polymer. This redox reaction changes the properties of polypyrrole, such as the conductivity, color, modulus of elasticity, and volume.

Two different schemes of redox are possible:

If PPy is doped with a large, immobile anion A− scheme 1 occurs, which schematically can be written as:

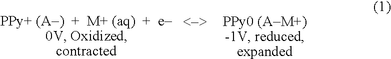

When PPy is reduced to its neutral state, cations M+including their hydration shell and solvent are inserted into the material and the material swells. When PPy is oxidised again the opposite reaction occurs, M+ cations (including hydration shell and solvent) leave the material and its volume decreases.

If, on the other hand, PPy is doped with small, mobile anions a−, scheme 2 occurs:

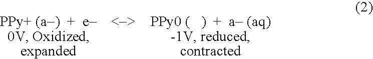

In this case the opposite behavior of scheme 1 occurs. In the reduced state, the anions leave the material and it shrinks. The oxidized state is now the expanded state and the reduced state the contracted. Non limiting example of ions A− is dodecylbenzene sulfonate (DBS−), of a− perchlorate (ClO4−), and of M+ sodium (Na+) or lithium (Li+).

This volume change can for instance be used to build actuators (See Q. Pei and O. Inganäs, “Conjugated polymers and the bending cantilever method: electrical muscles and smart devices”, Advanced materials, 1992, 4(4), p. 277-278. and Jager et al., “Microfabricating Conjugated Polymer Actuators”, Science 2000 290: 1540-1545). The actuators are commonly used in only three actuation schemes: linear, bending beam, and perpendicular expansion as shown in FIGS. 1a-c.

This redox reaction is usually driven in an electrochemical cell 130 that comprises a working electrode 134 (i.e. the conducting polymer or conducting polymer based actuator), a counter electrode 135, preferably a reference electrode 136, and an electrolyte 133 for instance in a beaker 132 (see FIG. 14). The appropriated potentials and currents to control the redox reactions are supplied by a control unit 131, such a potentiostat.

The electrolyte may be an aqueous salt solution, but may also be a solid polymer electrolyte, a gel, a non-aqueous solvent, and an ionic liquid as is know to those skilled in the art, but even biologically relevant environments such as blood (plasma), cell culture media, physiological media, ionic contrast solutions, etc can be used.

Examples of known actuators are illustrated in FIGS. 1a-1c.

Specifically, FIG. 1a illustrates a longitudinally expanding actuator 10 comprising a strip, tube or other body of a conducting polymer 13, which upon activation expands (13′) or contracts (13) in the longitudinal direction L.

FIG. 1b illustrates a bending actuator, which is based on a bi-layer structure 11, wherein the actuator element comprises an electroactive polymer layer 13 layered with an non-EAP layer 14. The actuator element has a fixed end and a movable end. Upon activation, the electroactive polymer layer 13 will expand (13′) or contract (13), whereas the non-EAP layer 14 is substantially unchanged, whereby the bending motion B is achieved. Such non-EAP layers may be conducting or non-conducting. Examples of suitable materials include, but are not limited to, metals, such as Au, Pt, Ti, and polymer materials.

FIG. 1c illustrates a volume expanding actuator 12, which comprises a body of electroactive polymer material 13, that upon actuation expands (13′) or contracts (13) in both direction D1 and D2.

The actuators disclosed above have many areas of application. However, to provide further areas of application for electroactive polymer actuators, additional actuator configurations and methods for their fabrication would be desirable.

### SUMMARY OF THE INVENTION

It is a general objective of the present disclosure to provide further electroactive polymer actuator configurations.

Specific objectives include providing electroactive polymer actuator configurations which can be used for holding/releasing small objects, which can be used for providing a tactile display, and/or which can be used for providing valves.

The invention is defined by the appended independent claim. Embodiments are set forth in the appended dependent claims, in the following description and in the drawings.

According to a first aspect, there is provided an actuator device, comprising a first electroactive polymer layer having an active electroactive polymer layer portion. The active electroactive polymer layer portion is controllably shiftable between a substantially neutral state and a buckled state.

The terms “neutral” and “buckled” refer to mechanical states of the active electroactive polymer layer portion. It is recognized that e.g. such a mechanically neutral state can, depending on which scheme is used, be achieved with the electroactive polymer in its electro-chemically neutral or activated state.

Such an actuator device provides an alternative, and in some applications also an improvement, to prior art actuators.

The active electroactive polymer layer portion may further extend between first and second spaced apart, fixed electroactive polymer layer portions.

The buckled state may be achieved by an in-plane expansion of the first electroactive polymer layer.

The electroactive polymer layer may, but does not need to, form part of a bi-layer structure, which further comprises an effectively non-electroactive layer.

In the substantially neutral state, the active electroactive polymer layer portion may be substantially planar.

The active electroactive polymer layer portion may, in the buckled state, be mechanically deformed relative to the neutral state, and in a plane perpendicular to the active electroactive polymer layer portion presents a curve having at least one point of inflection.

The electroactive polymer may be a conducting polymer.

The electroactive polymer layer may be formed on a substrate.

The substrate may comprise first and second fixing portions, to which the fixed electroactive polymer layer portions are attached.

The active electroactive polymer layer portion may extend over a release portion of the substrate, said release portion presenting substantially no effective adhesion to the active electroactive polymer layer portion.

The substrate may be substantially planar.

The electroactive polymer layer may, in the neutral state, be substantially parallel with the substrate.

The active electroactive polymer layer portion may extend over a recess, a slot or a hole in the substrate.

In one embodiment, the actuator may, in the buckled state, bulge away from the recess, slot or hole.

In one embodiment, the actuator may, in the buckled state, bulge towards or into the recess, slot or hole.

The actuator device may comprise means for releasably holding an object.

The holding means may be formed between the first electroactive polymer layer and the substrate.

The first electroactive polymer layer may at least partially cover at least one orifice, whereby said orifice may be openable or closable by said shifting between said substantially neutral state and said buckled state.

Hence, a valve function may be provided.

The orifice may be formed by the aforementioned recess, slot or hole in the substrate.

The orifice may be in fluid communication with a channel or through hole formed in the substrate.

The first and second fixed electroactive polymer portions may only partially encircle the orifice.

Thus the actuator device may operate as a valve controlling a fluid communication between the orifice and the space surrounding the actuator.

Thus, the actuator device may operate as a pump or, where the fixed electroactive polymer portions encircles multiple orifices, as a valve controlling a flow between these orifices.

A movable object may be positioned such that a contact force between said movable object and the actuator device is achievable or increasable when the actuator device is shifted to its buckled state, whereby the movable object is displaceable relative to the actuator device. Hence, the actuator may be used to induce a relative movement between two objects.

In yet another embodiment, the actuator device further comprises a second electroactive polymer layer, having a second active electroactive polymer layer portion, wherein the second active electroactive polymer layer portion is controllably shiftable between a substantially neutral state and a buckled state.

The second active electroactive polymer layer portion may extend between first and second spaced apart, fixed electroactive polymer layer portions of the second electroactive polymer layer.

The first and second fixed electroactive polymer layer portions may be displaceable relative to each other by the shifting between the substantially neutral state and the buckled state.

The holding means may be at least partially formed by first and second rigid elements, wherein said first fixed electroactive polymer layer portions are connected to the first rigid element and said second fixed electro-active polymer layer portions are connected to the second rigid element.

The first and second active electroactive polymer layer portions may be arranged to buckle in substantially opposite directions. In such an embodiment, the layers may be simultaneously controllable or individually controllable.

Hence, the buckling motion may be used to control a distance between two objects connected to a respective end of the electroactive polymer layer.

The above mentioned holding means is at least partially formed by said first and second electroactive polymer layers.

According to a second aspect, there is provided a pump device comprising at least one of the above mentioned actuator devices.

The pump device may further comprise an inlet and an outlet and at least three individually controllable actuator devices, whereby the actuator devices are sequentially controllable to provide a peristaltic motion from said inlet to said outlet.

According to a third aspect, there is provided an actuator array, comprising at least two of the above mentioned actuator devices.

In the actuator array, the actuator devices may be arranged to form a two-dimensional array.

In such a two-dimensional array, the actuator devices may be arranged along mutually perpendicular axes, along mutually oblique axes, or otherwise randomly or orderly over a surface.

In the actuator array, at least two, preferably all, actuator devices forming part of the actuator array may be simultaneously controllable.

In the actuator array, the actuator devices forming part of the actuator array may be simultaneously controllable to provide a change in a surface texture.

Alternatively, in the actuator array, at least two, preferably all, actuator devices forming part of the actuator array may be individually controllable.

According to a fourth aspect, there is provided a tactile display, comprising an actuator array as mentioned above. In such a display, the pixels may be formed by single, individually controllable actuator devices.

Also, by altering the surface structure of a surface, its reflective behavior may be altered, which may be used for providing a visual display device.

According to a fifth aspect, there is provided an object having a first friction surface, for interaction with an adjacent second friction surface, the first friction surface having a modifiable friction coefficient, the first friction surface comprising an actuator array as described above. The second friction surface may belong to another part of the same object, or to a separate object, interacting with the first object.

If the second friction surface is smooth, then the friction is reduced in the buckled state, due to the reduced contact surface. If the second surface is rough, then the friction may be increased in the buckled state, due to the engagement between the buckled actuator devices and protrusions or recesses in the second friction surface.

According to a sixth aspect, there is provided a sieve device, comprising an actuator device as described above, wherein an orifice is connected to a through hole.

In one embodiment of the sieve device, the first electroactive polymer layer covers at least two orifices.

In another embodiment of the sieve device, the device comprises at least two orifices, each orifice being covered by a respective, individually controllable electroactive polymer layer.

The actuator device and the applications thereof will now be described in more detail with reference to the drawings.

In another embodiment, the bi-layer structure may be provided only at the active electroactive polymer; layer portion, or only at a portion thereof. For example, the active electroactive polymer layer portion may have an extent that is smaller than the non-EAP layer.

In yet another embodiment, the electroactive polymer layer may present a movable edge portion, which is movable in a plane parallel with the electroactive polymer layer, but fixed in a plane perpendicular to the electroactive polymer layer.

In this embodiment, the electroactive polymer layer may present at least two such movable edge portions, said edge portions being spaced apart and separated by at least an active electroactive polymer layer portion.

The electroactive polymer layer may further present a fixed edge portion, which is spaced from the movable edge portion, said fixed edge portion and said movable edge portion being separated by at least an active electro-active polymer layer portion.

In yet another embodiment, the electroactive polymer layer may, in its neutral state, present a main plane presenting an angle of more than 0 degrees, preferably 90 degrees, to the substrate, and wherein the active electroactive layer portion, in the buckled state, bulges in a direction substantially perpendicular to the main plane.

According to another aspect, there is provided a valve comprising a channel having a channel wall, wherein at least a portion of said channel wall is provided with an actuator device as described above, arranged such that the actuator device, in the buckled state, reduces a cross sectional area of the channel.

According to yet another aspect, there is provided an elongate device having an outwardly facing wall provided with an actuator device as described above, such that, when the actuator is in the buckled state, an outer circumference of the device is greater than a corresponding outer circumference when the actuator is in the neutral state.

In the elongate device, the elongate device may have a substantially circular or elliptic cross section, and the active electroactive polymer layer portion may extend substantially around an entire circumference of the device.

According to another aspect, there is provided a dispenser device, comprising a cavity for receiving a fluid to be dispensed, a dispensing channel, and an actuator device comprising a first electroactive polymer layer, having an active electroactive polymer layer portion. The active electroactive polymer layer portion is controllably shiftable between a substantially neutral state and a buckled state, wherein the active electroactive polymer layer portion bulges into the cavity.

According to another aspect, there is provided a first method for fabricating a buckling actuator, the method comprising providing an electroactive polymer layer on a substrate, such that a portion of the electroactive polymer layer is movable relative to the substrate.

According to another aspect, there is provided a second method for fabricating a buckling actuator, the method comprising providing an electroactive polymer layer on a substrate and removing a portion of the substrate, while leaving a fixed active material portion adhering the electroactive polymer layer to the substrate.

According to another aspect, there is provided a third method for fabricating a buckling actuator, the method comprising providing a sacrificial layer on a substrate, and providing an electroactive polymer layer on said sacrificial layer and in contact with the substrate, and thereafter at least partially removing the sacrificial layer.

According to another aspect, there is provided a fourth method for fabricating a buckling actuator, the method comprising clamping an edge portion of an electroactive polymer membrane between a pair of clamping members.

### BRIEF DESCRIPTION OF THE DRAWINGS

FIGS. 1a-1c illustrate prior art actuation principles.

FIGS. 2a-2f illustrate a first embodiment of a buckling actuator 20, and variations 25, 26 thereof.

FIGS. 3a-3d illustrate a second embodiment of a buckling actuator 30.

FIGS. 3e-3f illustrate a three-dimensional buckling actuator.

FIGS. 3g-3h illustrate another version of the first embodiment.

FIGS. 3i-3h illustrate a buckling actuator having only one fixed portion.

FIGS. 3k-3l illustrate a buckling actuator, which buckles in a direction perpendicular to the substrate.

FIGS. 4a-4c illustrate a third embodiment of a buckling actuator 40.

FIGS. 5a-5c illustrate a fourth embodiment of a buckling actuator 50.

FIGS. 6a-6b illustrate a controllable friction interface 45 using a buckling actuator.

FIGS. 7a-7b illustrate a fifth embodiment of a buckling actuator 60.

FIGS. 8a-8c illustrate a sixth embodiment of a buckling actuator 70.

FIGS. 9a-9b illustrate sieve devices 75, 76 utilizing the seventh embodiment of the buckling actuator 70.

FIGS. 10a-10b illustrate a seventh embodiment of a buckling actuator 80.

FIGS. 11a-11b illustrate a eight embodiment of a buckling actuator 90.

FIGS. 12a-12f illustrate a ninth embodiment of a buckling actuator 100, and variations 105, 65, 66 thereof.

FIGS. 13a-13i illustrate peristaltic pumps 110, 120, 125 utilizing buckling actuators.

FIG. 14 illustrates an electrochemical system comprising at least one of the buckling actuators described herein.

FIGS. 15a-15d illustrate further embodiments of buckling actuators.

FIGS. 16a-16b illustrate an embodiment of a buckling actuator having a more controlled buckling behavior.

FIGS. 17a-17e illustrate alternative methods for producing a buckling actuator.

FIGS. 18a-18e illustrate embodiments of a dispensing device.

### DESCRIPTION OF EMBODIMENTS

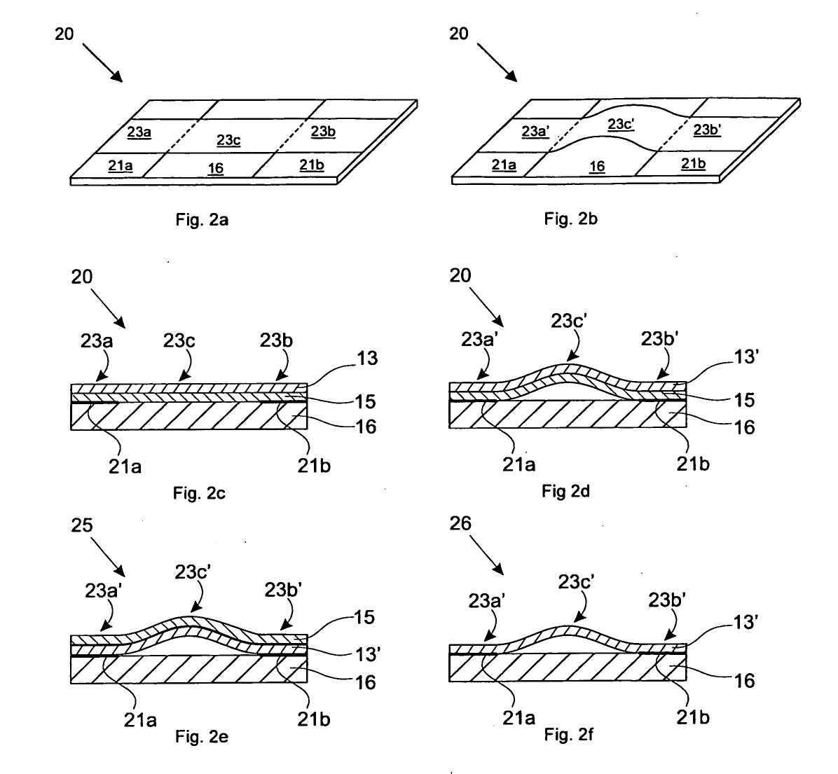

FIGS. 2a-2f illustrate a first embodiment of a buckling actuator 20. The buckling actuator comprises a buckling membrane 23 arranged on a substrate 16. In this example, the membrane 23 comprises an electroactive polymer layer, such as PPy(DBS), 13 and optionally a non-EAP layer 15, which may comprise gold (Au) and which may be fabricated using the differential adhesion method. In this description, reference is made to Au for illustration only, while the invention can be used with any known or subsequently developed/discovered non-EAP layer. Such non-EAP layers may be conducting or non-conducting. Examples of suitable materials include, but are not limited to, metals, such as Au, Pt, Ti, and polymer materials. For details regarding this fabrication method, it is referred to U.S. Pat. No. 6,103,399, the entire contents of which is hereby incorporated herein by reference.

Using standard patterning technologies, such as microfabrication and photolithography, the substrate can be divided in good adhesive areas 21a, 21b and poor adhesive areas 16. This can, for instance, be achieved by choosing Si as the substrate material 16 and a thin patterned layer of Cr as the adhesive layer 21a, 21b. A non-EAP layer of Au 15 is then deposited, onto which the electroactive polymer 13 is deposited. Thereafter, the Au/EAP layer is patterned. Thus, the portions of the membrane 23, 23′ that overlap and adheres to the exposed Cr surfaces 21a, 21b form fixed portions 23a, 23b, 23a′, 23b′ and the portions of the membrane 23, 23′ that overlap, but does not adhere to, the exposed Si surface 16, form an active portion 23c, 23c′.

In FIGS. 2a, 2c the actuator is in its contracted state, which is the inactivated or oxidized state when PPy(DBS) is chosen as the electroactive polymer. By applying a negative potential, the PPy(DBS) 13 is reduced and the electroactive polymer material expands (following scheme 1). In the areas where the Au layer 15 is in contact with the Cr layer 21a, 21b, the actuator remains attached to the substrate. In the areas where the Au layer is in direct contact with the bare Si substrate 16, the actuator can move freely due to the poor adhesion between Au and Si. As a result of the expansion of the PPy(DBS), the bi-layer actuates in a buckling movement between the fixed portions 23a, 23b of the membrane 23, 23′.

FIG. 2e and FIG. 2f show two possible variations of the buckling actuator, both of which illustrated in the buckled state.

FIG. 2e shows a buckling actuator 25 comprising an inverted bi-layer (with respect to FIG. 2b-d). The buckling membrane 23 comprises a non-EAP layer 15 on top of an EAP layer 13′.

FIG. 2f shows a buckling actuator 26 comprising a single EAP layer 13′. Other multilayer configurations are contemplated. In the following drawings, the adhesive area/layer 21a, 21b has been omitted for clarity.

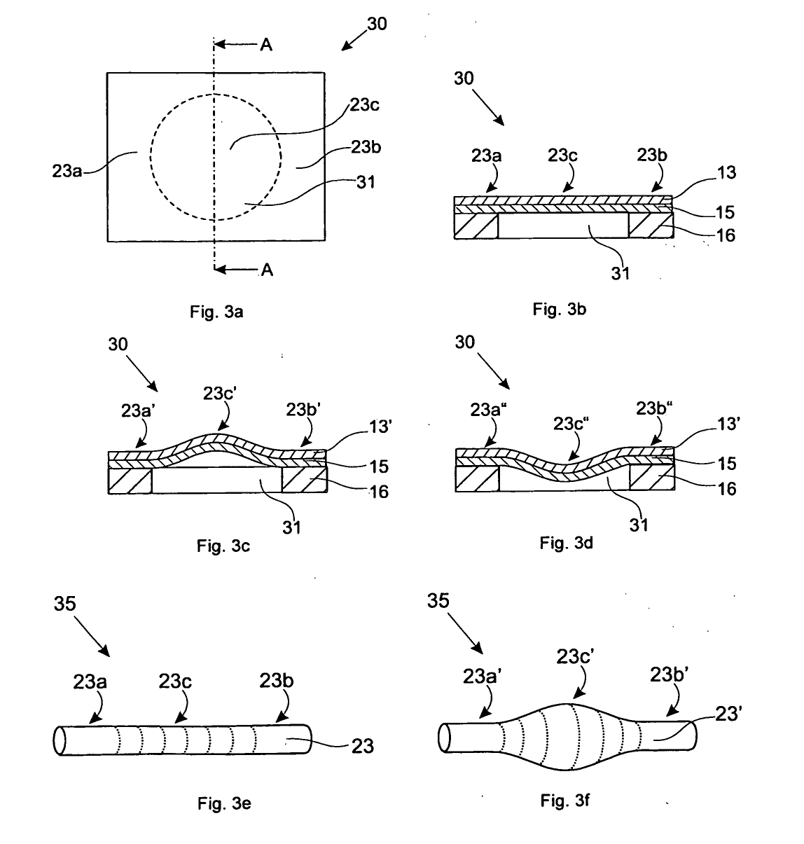

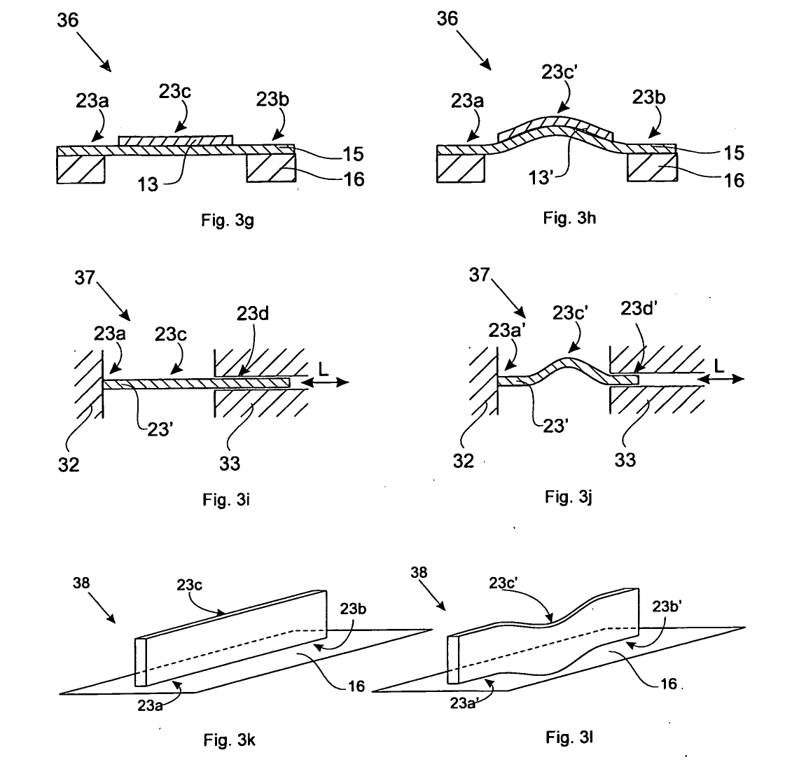

FIGS. 3a-3d show a second embodiment, wherein the buckling actuator 30 (FIG. 3a-3d) comprises a substrate 16 with a hole or a recess 31, which may be provided by etching, drilling or similar methods, covered by the buckling membrane 23 that comprises an electroactive polymer 13 and, optionally, a non-EAP material layer 15, such as Au. The membrane 23 comprises first and second fixed portions 23a, 23b and an active portion 23c. FIGS. 3b-3d illustrate sectional views of the actuator 30 of FIG. 3a, taken along the line A-A. The part of the buckling membrane that covers the hole or recess 31 is free to move, i.e. forms the active portion. FIG. 3b. shows the EAP in the contracted or neutral state, which is the inactivated state for PPy(DBS). When actuating the actuator (expanding the EAP layer 13′), the active portion 23c′, 23c″ of the membrane buckles either upwards (FIG. 3c) or downwards (FIG. 3d).

FIGS. 3e-3f illustrate a 3D buckling actuator configuration, wherein the actuator 35 comprises a substantially tubular membrane 23, and wherein fixed electroactive polymer layer portions 23a, 23b may be attached to fixed members (not shown) having a correspondingly tubular shape. When activated, the active electroactive polymer layer portion 23c buckles radially.

In one embodiment, the fixed members may be movable relative to each other, whereby the buckling may alter the distance between them.

In another embodiment, the fixed members may be mutually fixed, e.g. form parts of a continuous tubular member, whereby the buckling provides an increase in diameter of a portion of the tubular member.

FIGS. 3g-3h illustrates an actuator 36 having a “partial” bi-layer structure. The actuator has a non-EAP material 15, having two fixed ends 23a, 23b, attached to respective fixing parts, which may be formed by the substrate 16, as indicated in FIGS. 3g-3h. An active electroactive polymer layer portion 23c is provided on or under the non-EAP material 15. This active electroactive polymer layer portion 23c has an extent which is smaller than an extent of the non-EAP layer. For example, the active electroactive polymer layer portion 23c may extend up to, but not overlapping edges of the fixing parts. As another example, the active electroactive polymer layer portion 23c may present an edge that is at a distance from at least one of the fixing parts.

FIGS. 3i, 3j illustrate another embodiment of a buckling actuator 37, wherein the electroactive polymer layer 23 has one fixed portion 23a, which may be attached to a fixed part 32 in a cantilever manner. The electroactive polymer layer has a sliding portion 23d, which is spaced apart from the fixed portion 23a, and which may interact with a guide part 33, sodas to be slidable in a direction L, which may be substantially parallel with the main plane of the electroactive polymer layer 23. The guide part 33 may be provided with a guide slot, into which the sliding portion 23d is received. This embodiment may be provided by using single or bi-layer actuators.

In another embodiment, which is not illustrated, the electroactive polymer layer 23 may have two spaced-apart sliding portions 23d, as illustrated in FIG. 3i. However, this embodiment would require a bi-layer actuator structure.

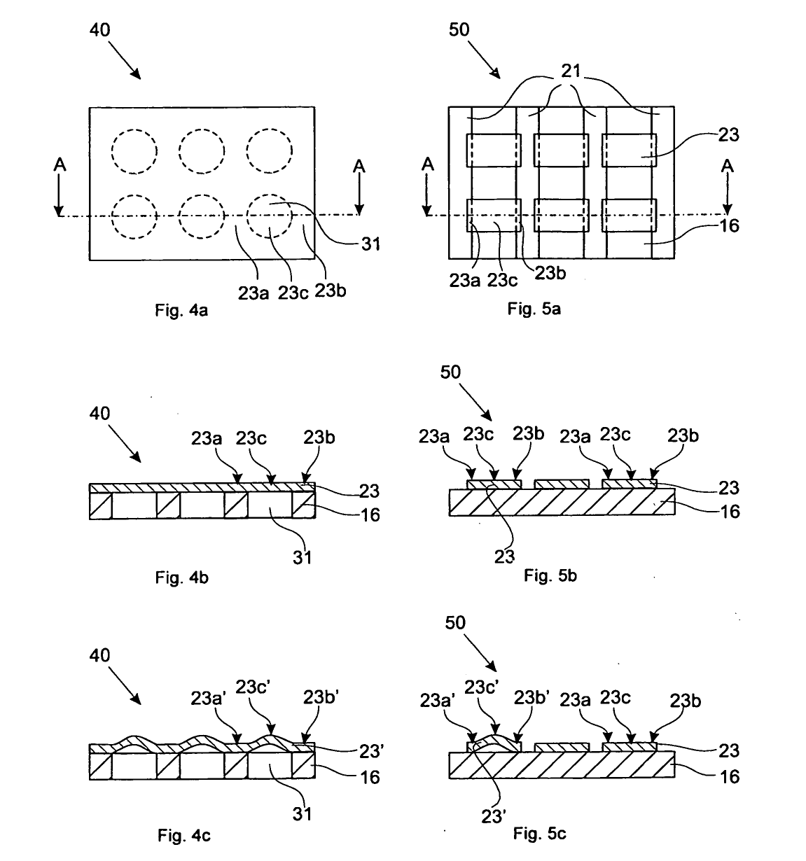

FIGS. 3k-3l illustrate yet another buckling actuator 38, which is arranged to buckle in a direction parallel with the substrate. The buckling actuator 38 is configured as the ones described in FIGS. 2a-2f, but instead of having its main plane parallel with the substrate, the main plane is substantially perpendicular to the substrate. Other angles between 0-90 degrees may also be provided. The buckling actuator 38 may have the form of a sheet or a beam. FIGS. 4a-4c show a third embodiment. The buckling actuator as described with reference to FIGS. 3a-3d is taken to exemplify this embodiment. FIGS. 4b-4c illustrate sectional views of the actuator 40 of FIG. 4a, taken along the line A-A. The buckling device 40 of FIGS. 4a-4c comprises a number of actuators, which may be ordered in an array. When actuating the electroactive material, the membrane or membranes 23, comprising several (six in FIG. 4) sets of first and second fixed portions 23a, 23b and active portions 23c, may buckle and protrude at each individual actuator/hole 31 (only one numbered) as shown in FIG. 4c. This creates a change in the surface texture of the device 40. Such a surface texture may be utilized to provide a surface having a modifiable friction coefficient. It is noted that a device of this type may be achieved also with the holes replaced with areas having poor adhesion. The holes, or recesses, 31 are not necessary for this embodiment. Also, according to yet another embodiment, the membranes 23 may buckle into the holes 31.

For example, if a surface interacting with the device 40 has a smooth surface, activating the device 40 reduces the contact area at which the friction occurs, and thereby reduces the friction of the surface.

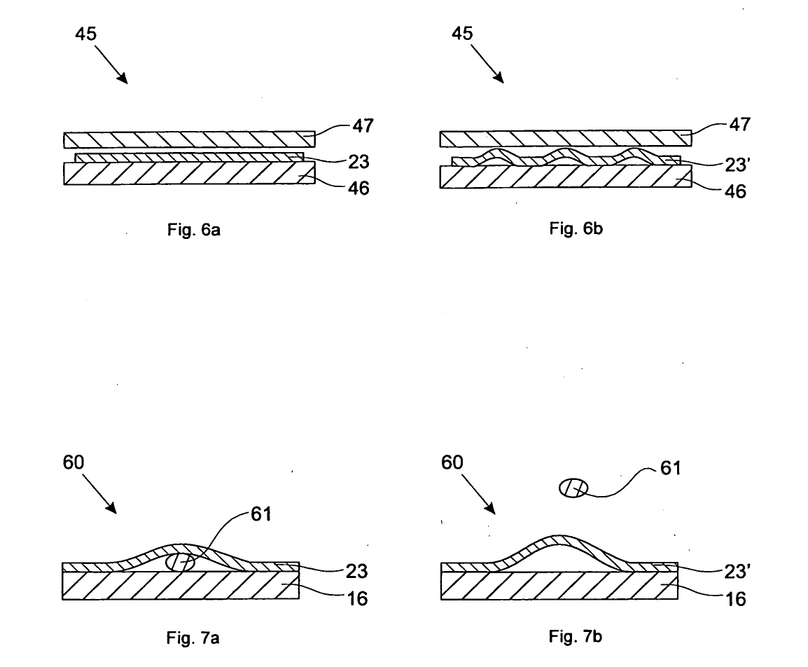

Such a device 45 is illustrated in FIG. 6a, b. A first object/part 46 comprises an area containing such buckling actuator area 23c. When expanding the EAP material, this area buckles (23c′, FIG. 4c) and the contact area between the layer 23 and the surface of a second object/part 47 (thus between objects/parts 46 and 47) is reduced and thereby the friction is reduced. The objects 46 and 47 may be parts of a single device that can move in respect of each other or two separate devices, such as “inter sliding” tubes, i.e. tubular devices, which interact in a telescoping manner. Such devices could be used in medical devices. In another embodiment, both interacting surfaces may have such buckling devices 40, whereby the friction between the interacting surfaces may be controllable by altering one or both surface textures. Two surfaces having interacting buckling devices may be individually controllable. For example, in a first mode one of the interacting surfaces may have outwardly buckling actuators, whereas the other one of the surfaces has outwardly or inwardly buckling surfaces, whereby actuators of the two interacting surfaces engage each other to provide increased friction.

Conversely, if the surface interacting with the device 40 has a rough surface, activating the device 40 provides for increased friction through the engagement of protruding membranes and protrusions on the other surface.

FIGS. 5a-5c. show a fourth embodiment. FIGS. 5b-5c illustrate sectional views of the actuator 50 of FIG. 5a, taken along the line A-A. This is also a buckling device 50 that can change the surface texture of the device. The device 50 is similar to that of the buckling device 40, in that it contains a number of buckling actuators, which may be arranged in an array of membranes 23, comprising several (six in FIG. 5) sets of first and second fixed portions 23a, 23b and active portions 23c. In this case the buckling actuators of FIG. 2 are used to exemplify the embodiment, and each actuator can be individually controlled. The electrical connections to each individual buckling actuators have been omitted from FIGS. 5a-5c for clarity. FIGS. 5b-5c show a cross section of the device 50 at, for instance, the second row. Only the actuator of the second row, first column is actuated (23a′, 23b′, 23c′) in FIG. 5c. In this way, the surface texture can be changed on specific areas of the device 50. This can for instance be used to create a tactile display where each individual buckling actuator represents a “pixel”.

FIGS. 7a-7b illustrate a fifth embodiment. The buckling actuator 60 is used to hold and release an object 61. The actuator 60 may be activated and an object 61 may be placed between the substrate 16 and the buckling membrane 23′, after which the actuator may be deactivated and the object is held by actuator (FIG. 7a), squeezed between the underside of the active portion of the membrane 23 and the substrate 16. The object 61 may be only partially inserted into the actuator 60. The actuator, that can be part of a larger tool, may be brought to the place where the object should be applied and then the actuator is activated once more to release the object at the appropriate position (FIG. 7b). The larger tool could for instance be a medical device, such as a catheter, and the object 61 may be an implant.

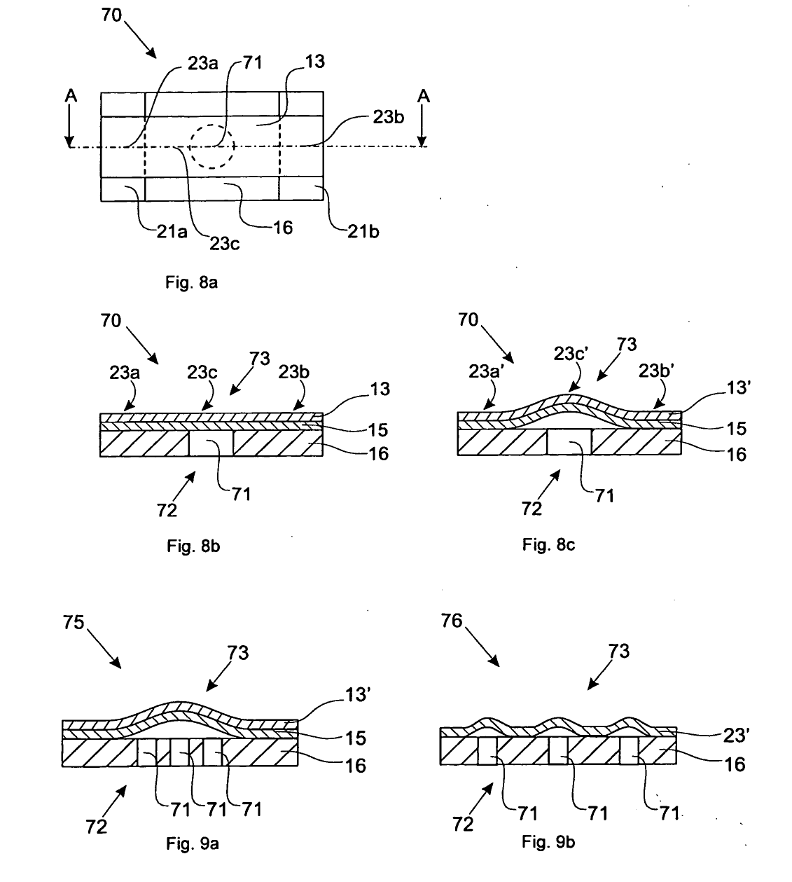

A sixth embodiment is shown in FIGS. 8a-8c. FIGS. 8b-8c illustrate sectional views of the actuator 70 of FIG. 8a, taken along the line A-A. The buckling actuator 70 is attached to the substrate at least two sides, or spaced apart portions, which may be perpendicular to the line A-A and open at least one side or portion, which may be parallel with the line A-A, as illustrated in FIGS. 8a-8c. In this example the buckling strip of FIG. 2 is used for illustration. The substrate 16 comprises at least one orifice 71, which may be connected to a channel or a through hole in the substrate 16. The actuator 70 is mounted in a system in such a way that the actuator divides the system in two parts, here called the bottom side 72 and the top side 73. The system may be a fluidic channel (not shown) where 72 represents a downstream part and 73 represents an upstream part, or vice versa. Likewise the system may be a container, where 72 is the inside of the container and 73 represents the outside or surroundings, or vice versa.

When the actuator is activated the at least one orifice is opened (membrane activated 23a′, 23b′, 23c′) and a fluidic path between the parts 72 and 73 is established, thus enabling the transport of fluid, molecules, particles, species, and/or objects between the sides or parts 72 and 73.

FIGS. 9a-9b show variants of the device 70, constructed as sieves that can be opened or closed.

FIG. 9a shows a sieve device 75 in the opened state, the sieve comprising a single buckling actuator (comprising an EAP layer 13 and optionally a non-EAP layer 15) controlling multiple holes or pores 71 simultaneously.

FIG. 9b shows a sieve or a sieve array device 76 comprising a plurality of buckling valves, such as the device 70, with each individual actuator opening a single hole or pore.

Such sieves could for instance be used as an artificial valve in the urethra when suffering from urinary incontinence.

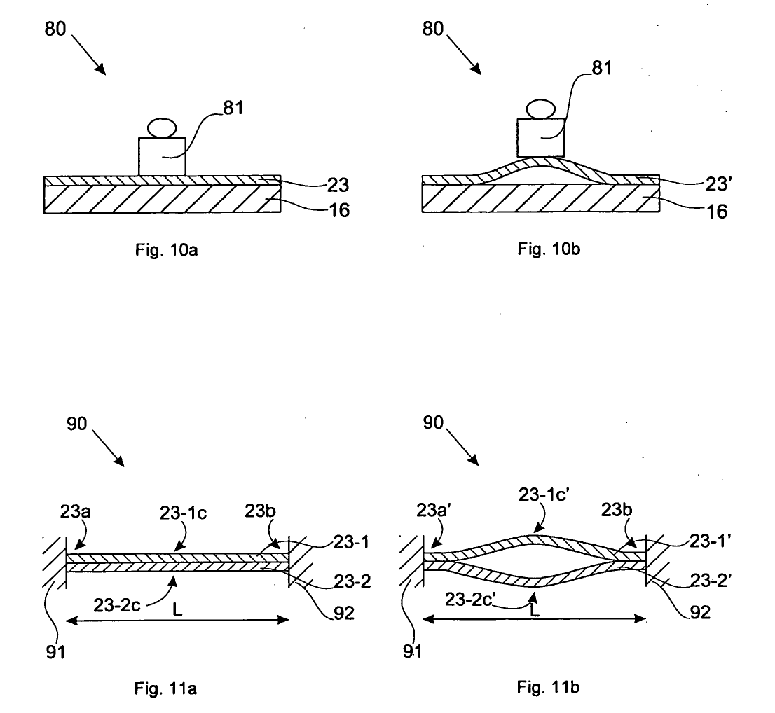

A seventh embodiment is schematically illustrated in FIGS. 10a-10b. The buckling actuator 80 may be utilized to lift or move an object 81. Both the object 81 and the substrate 16 (or actuator 80) may be part(s) of a larger device where the buckling actuator is utilized to create the movement between two separate parts 81 and 16. It is contemplated that the object 81 also could be a liquid that is moved or pushed.

FIGS. 11a-11b illustrate an eighth embodiment. The buckling actuator 90 comprises two buckling membranes 23-1, 23-2, the fixed portions 23a, 23b of which are attached to two rigid, spaced apart parts 91 and 92. The membranes further comprise active portions 23-1c, 23-2c. The rigid parts 91 and 92 are at a fix distance between one and other, and may buckle in opposite directions. Actuating both membranes 23-1, 23-2; 23-1′, 23-2′ creates a buckling-debuckling motion, when the active portions 23-1c′, 23-2c′ of the membranes buckle/unbuckle.

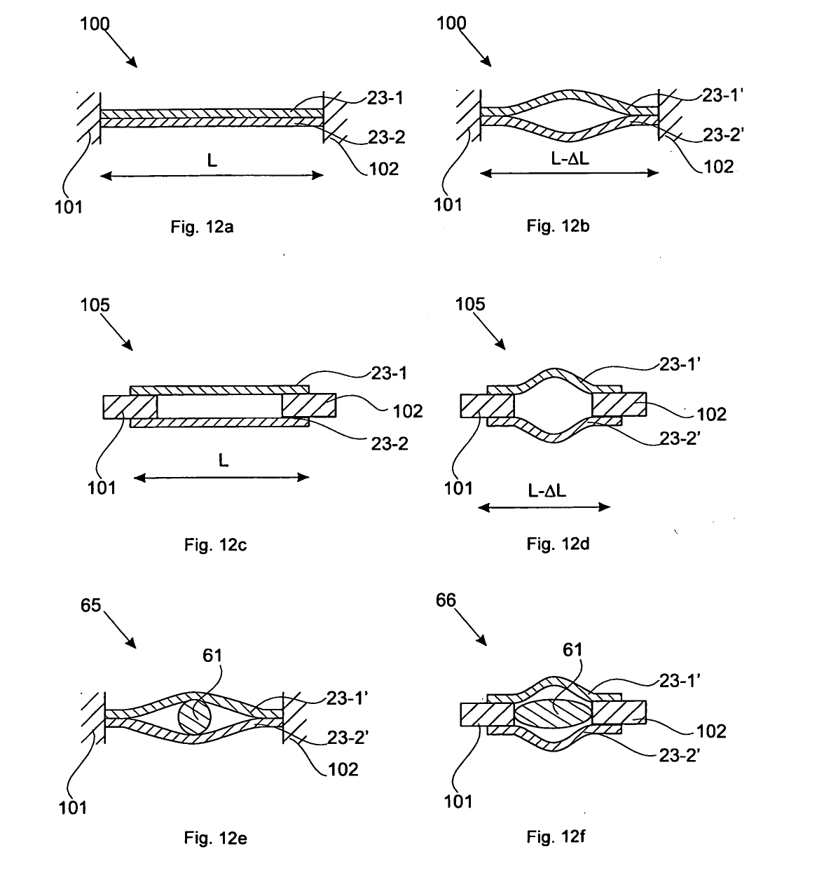

A ninth embodiment is disclosed in FIGS. 12a-12f. The buckling actuator 100 comprises two buckling membranes 23-1, 23-2, the fixed portions 23a, 23b, 23a′, 23b′ of which are attached to two rigid, spaced apart parts 101 and 102. The membranes further comprise active portions 23-1c, 23-2c. The rigid parts 101 and 102 can move freely with respect to one and other. The respective ends of the membrane may be fixed to the rigid parts 101, 102, e.g. in a cantilever manner. Actuating both membranes 23-1, 23-2; 23-1′, 23-2′ creates a buckling motion, whereby a distance between the rigid parts 101 and 102 decreases. When the membranes 23-1c′, 23-2c′ are returned to the flat state the distance between the two rigid parts 101, 102 increases again. The actuator 100 may be part of a larger device where it is used to create movement between rigid parts 101, 102 of the device. For instance the rigid part 101 could be the back side of a tubular construction and the rigid part 102 could be a piston that can move within this tube driven by the buckling EAP actuators.

FIGS. 12e and 12f illustrate embodiments constructed in a manner similar to those of FIGS. 12a-12d, and which may be used to hold or clamp objects 61. The devices 65 and 66 in FIGS. 12e, 12f hold or clamp an object 61 between a pair of oppositely buckling actuators 23-1, 23-2; 23-1′, 23-2′, or between a pair of spaced apart rigid members 101, 102.

The objects could be held or clamped between the two buckling membranes 23-1′, 23-2′, as illustrated in FIG. 12e, whereby the buckling membranes 23-1, 23-2; 23-1′, 23-2′ operate as described with reference to FIG. 12a-12b.

Alternatively, the object could be held or clamped between the two rigid elements 101 and 102, as is illustrated in FIG. 12, whereby the buckling actuators are used to control the distance between the rigid members in the manner described with reference to FIG. 12c-12d.

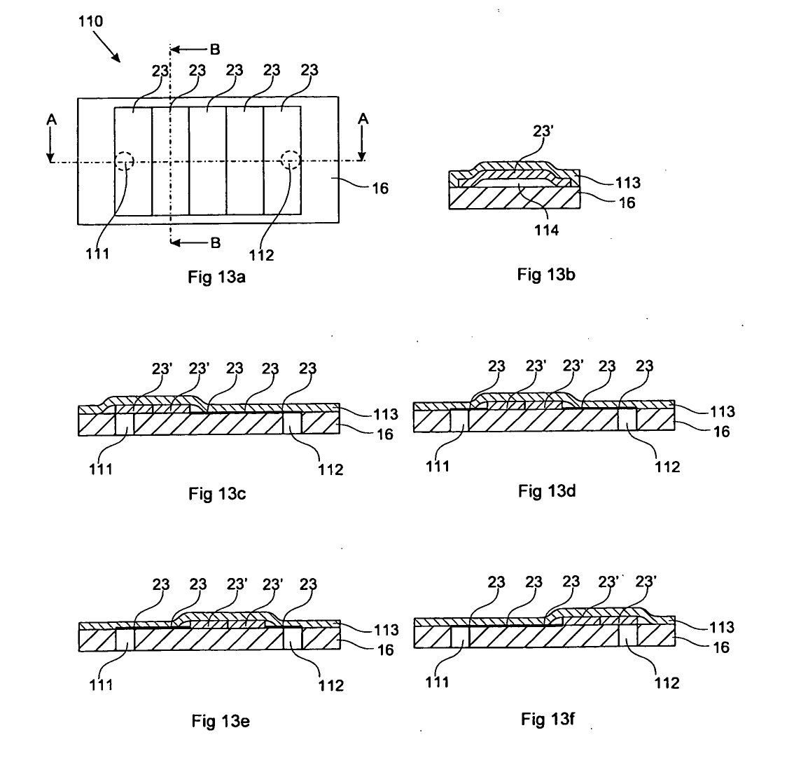

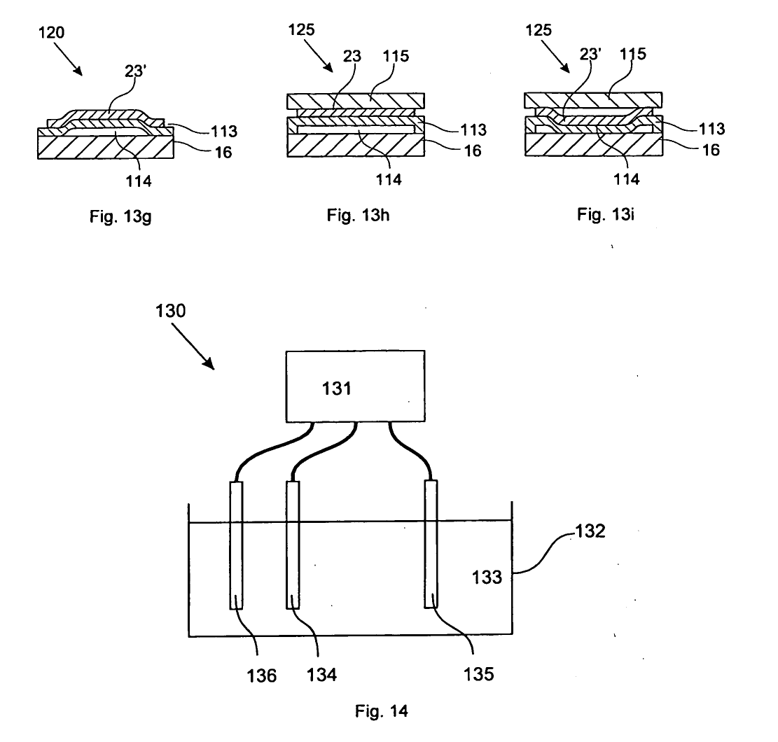

FIGS. 13a-13i show a tenth embodiment. FIG. 13a shows a top view of a fluid pump 110 that is actuated by a plurality of buckling actuators, and where the fluid to be pumped is moved in peristaltic-like motion. FIG. 13b illustrates a sectional view of the fluid pump 110 of FIG. 13a, taken along the line B-B. FIGS. 13c-13d illustrate sectional views of the fluid pump 110 of FIG. 13a, taken along the line A-A. In this example the pump comprises 5 individual buckling actuators 23, an inlet 111 and an outlet 112. A membrane 113 may be arranged to enclose the actuators on the top side of the pump. (The membrane 113 has been omitted from the drawing of FIG. 13a for clarity). FIG. 13b shows a cross section along the line B-B and FIGS. 13c-13f a cross section along the line A-A at different times of a pumping cycle.

A pump cycle starts by a first step activating (buckling) the first actuator(s) near the inlet (FIG. 13c). Liquid from the inlet is pumped into the fluid cavity 114 formed by the opened actuators 23′ and membrane 113.

In a second step, the next actuator in line is activated and the first actuator is deactivated simultaneously, whereby the liquid is pushed to the right (FIG. 13d).

In a third step, the second actuator is closed and a fourth is opened (FIG. 13e) and liquid is moved yet a step to the right.

In a fourth step, the third actuator is closed and the last actuator is opened and the liquid is moved yet another step to the right (FIG. 13f).

In the fifth cycle step, actuators four and five are closed pushing the liquid into the outlet and actuators one and two are opened, enabling liquid to enter the pump from the inlet thus completing the pump cycle (FIG. 13c).

Repeating the cycle results in a pumping effect.

FIGS. 13g-13i illustrate sectional views of alternative pump embodiments, taken along a line corresponding to the line B-B of FIG. 13a.

It is contemplated that the buckling actuators may also be mounted on the reverse side of the membrane so that the actuators are not in direct contact with the liquid to be pumped. This can be achieved by either “laminating/mounting” the actuators 23 on the reverse (or outer) side of the membrane 113 as is schematically shown in FIG. 13g (a cross section along line B-B, the actuator being in the buckled state). In this case the pump works similar as shown in FIGS. 13a-13i.

Another alternative, is to mount the actuators on the membrane 113, so that when they are flat (the EAP layer being in the contracted state), the membrane is opened and creates a cavity 114 for the fluid (FIG. 13h a cross section along the line B-B) and when the actuators are buckled (the EAP layer being in the expanded state) the membrane is pushed towards the substrate and thus closing the cavity (FIG. 13i a cross section along the line B-B).

Optionally, a second substrate 115 may be provided, parallel with the first substrate 16, whereby the second substrate may provide an abutment for the actuator 23.

In addition, the pump may comprise 3 or more buckling actuators (the example showed 5) and may comprise further layers and parts.

In all embodiments, the buckling membrane 23 may comprise only one single layer of an EAP or multiple layers. It may further comprise one or more non-EAP layers on either side of the EAP layer(s).

For example, such non-EAP layers may include one or more of a metal layer, such as Au, a soft layer providing enhanced stability and a sticking-preventing layer. In one embodiment, a metal layer is arranged in contact with the EAP layer. The metal layer may be arranged above or below the EAP layer. A soft layer, if any, may be provided on top of the EAP and metal layers and the sticking-preventing layer may be provided as an outwardly facing layer, thus protecting the underlying layers.

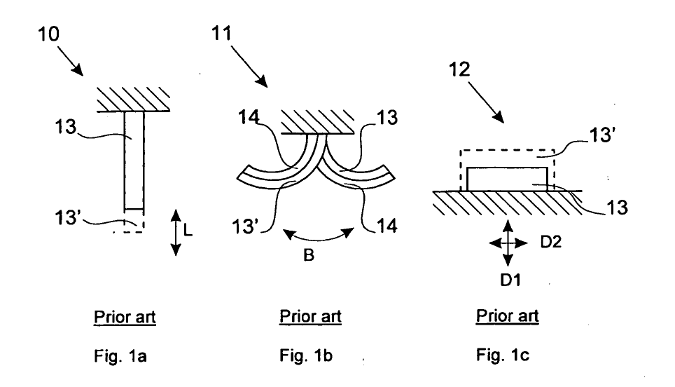

FIG. 14 schematically illustrates an electrochemical system 130. The system comprises a control unit 131 (e.g. a potentiostat), a container 132 containing an electrolyte 133, a working electrode 134, counter electrode 135, and a reference electrode 136. The electrodes 134 through 136 may be connected to the control unit 131 by cables or wirelessly. The working electrode is the electroactive polymer actuator such as sketched in FIGS. 1a-1c or the buckling actuator as disclosed herein. The actuator may be an active part of a surgical tool, wherein the container 132 may be the human body and the electrolyte 133 may be a physiological fluid. An examples of such tools are given WO 00/78222.

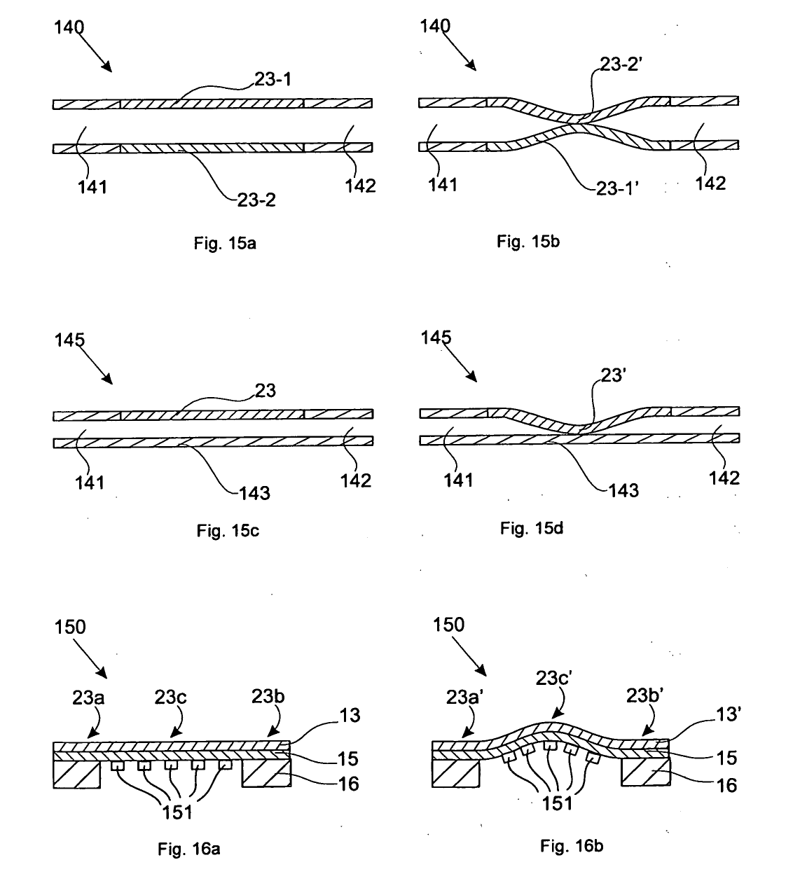

In FIGS. 15a-15b, another buckling actuator 140 is illustrated. This actuator 140 is arranged in a channel, duct or pipe having first and second fixed-cross section pipe portions 141 and 142, and one or more membranes 23-1, 23-2, which are arranged to buckle inwardly, thereby reducing or closing, upon actuation, the flow cross section of the channel between the ends 141 and 142.

The pipe may either have a square or rectangular cross section, with membranes 23-1, 23-2 arranged on opposing walls, e.g. on only one pair of opposing walls.

Alternatively, the pipe may have a circular, elliptic or similar cross section, whereby the walls bulge inwardly upon actuation of the membrane 23-1′, 23-2′.

FIGS. 15c-15d illustrate an alternative embodiment. In this embodiment, the buckling membrane 23 of the buckling actuator 145 is arranged opposite to a non-buckling channel wall 143, between first and second fixed-cross section pipe portions 141 and 142. Actuating the membrane 23′ decreases or closes the flow cross section of the channel.

The electroactive polymer may be a conducting polymer comprising pyrrole, aniline, thiophene, paraphenylene, vinylene, and phenylene polymers and copolymers thereof, including substituted forms of the different monomers.

As illustrated in FIGS. 16a-16b, any one of the buckling membranes described herein may further be provided with a reinforcing structure 151 having an unevenly distributed bending stiffness and that the reinforcing structure 151 may be spread over any of the layers 13, 14, 15 to control the movement of the microactuator.

In FIGS. 16a-16b, the reinforcement structure 151 is illustrated a separate layer 151 provided as ribs on the underside of the non-EAP layer 15. More configurations for integrating such reinforcement structures 151 can be found in U.S. Pat. No. 6,933,659, the entire contents of which is hereby incorporated herein by reference.

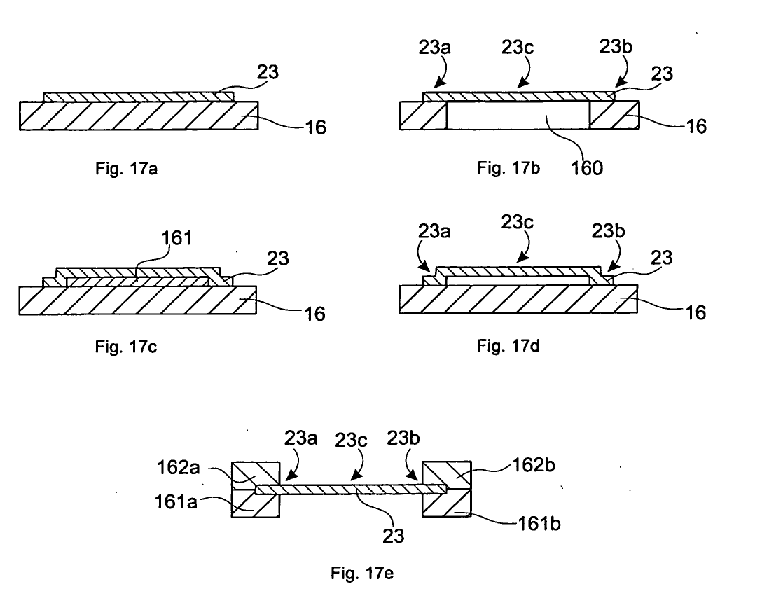

FIGS. 17a-17e illustrate alternative, but non-limiting, fabrication methods. FIGS. 17a-17b illustrate fabricating a buckling membrane by etching a hole, cavity, etc 160 in a substrate 16, as is known to those skilled in the art.

One way of fabricating membranes can be found in WO 2004/092050, the entire contents of which is hereby incorporated herein by reference. After etching the hole 160 the buckling membrane 23 may be partitioned in fixed portions 23a, 23b and an active electroactive polymer layer portion 23c.

Another way of fabrication a buckling membrane is by using a sacrificial layer method, as is illustrated in FIGS. 17c-17d. The buckling membrane 23 is achieved by providing a sacrificial layer 161 on the substrate, prior to providing the buckling membrane 23. The buckling membrane is provided over an area that is larger than the sacrificial layer 161, such that fixing portions 23a, 23b may be provided. Thereafter, the sacrificial layer 161 is etched away, such that a small space is formed between the active electroactive polymer layer portion 23c and the substrate 16.

Yet another way of creating a buckling membrane is by clamping or mounting the buckling membrane 23 between two rigid parts 162a, 162b and 163a, 163b, as is illustrated in FIG. 17e. These rigid parts maybe two rings 162 and 163, or a ring 162 clamped onto a larger rigid frame 163.

Only the last step (e.g. etching the hole, sacrificial layer, clamping) is shown in FIGS. 17a-17e. Further fabrication steps, for instance patterning, are known to those skilled in the art and can be found for instance in Jager et al., “Microfabricating Conjugated Polymer Actuators”, Science 2000 290: 1540-1545.

Yet another method for manufacturing a buckling membrane is to provide the Au EAP and any non-EAP layer first, after which a frame, which may be annular in shape, is affixed using additive methods onto the EAP or non-EAP layer. Examples of such additive methods are electroplating or electroless plating, photopatternable polymers/resins such as SU8 or polyimide, glueing or laminating a frame. Such a buckling membrane may be mounted on a substrate.

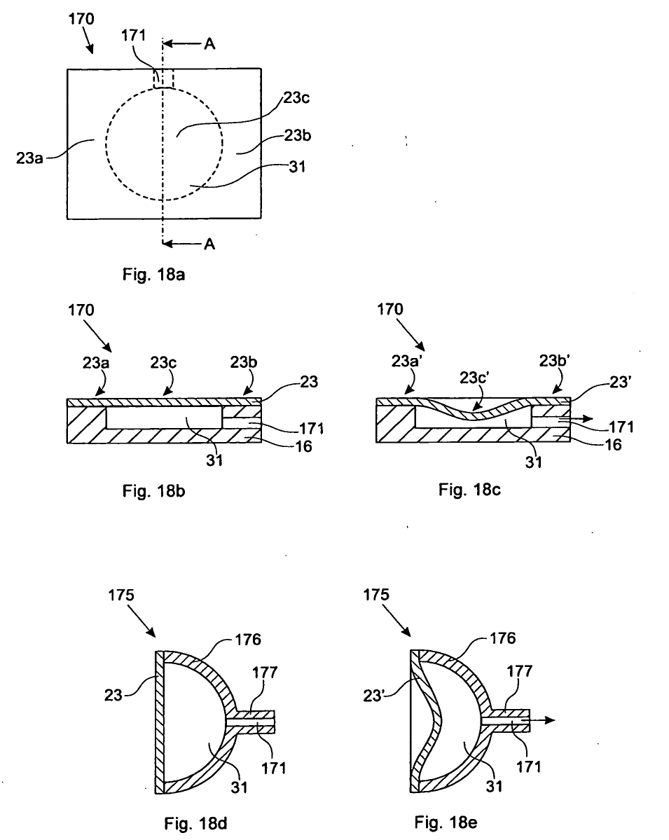

FIGS. 18a-18c illustrate a dispenser/pipette 170 comprising an EAP actuated buckling membrane 23, such as the ones described above. The dispenser/pipette comprises a body 16 and a membrane 23a, 23b, 23c, which together define a cavity 31, and an outlet channel 171 from the cavity to the outside of the dispenser 170. The body may be formed by a planar substrate, in which a cavity-forming recess is arranged, and the outlet channel 171 is formed.

The cavity 31 may be filled with a liquid/fluid to be dispensed or pumped. When the membrane 23 is actuated, an active electroactive polymer layer portion thereof buckles inwardly, whereby the cavity 31 is pressurised and the fluid is pushed out of the cavity 31 through the outlet 171.

FIGS. 18d-18e illustrate an alternative embodiment of a dispenser/pipette 175, which operates in substantially the same manner as the one described with respect to FIGS. 18a-18c. The dispenser 175 comprises a body 176, which may be semi-spherical and/or be cap shaped. The dispenser may be provided with a protrusion/extension 177 with an outlet channel 171, and an EAP actuated buckling membrane 23. The membrane 23 may be arranged to form a base portion of the body 176. As with the dispenser device 170, actuating the membrane 23 will expel the fluid from the cavity 31.

Instead of expelling a liquid the dispenser devices 170, 175 can also be used to take in a solution, liquid, fluid by reversing the procedure. First, the membrane 23 is actuated to its buckled state. The dispenser 170, 175 is brought into contact with the solution to be acquired and the membrane is deactived into its flat state, thus taking in the fluid.

The outlet 171 may be coupled to a secondary fluid path, such as a tube or (microfluidic) channel.

1.-52. (canceled)

53. An actuator system, comprising:
an actuator device having a first electroactive polymer layer, having an active electroactive polymer layer portion, and
a counter electrode, which forms a unit that is separate from the actuator device,
wherein the active electroactive polymer layer portion is controllably shiftable between a substantially neutral state and a buckled state.

54. The actuator system as claimed in claim 53, wherein the active electroactive polymer layer portion extends between first and second spaced apart, fixed electroactive polymer layer portions.

55. The actuator system as claimed in claim 53, wherein the buckled state is achieved by an in-plane expansion of the first electroactive polymer layer.

56. The actuator system as claimed in claim 53, wherein the electroactive polymer layer forms part of a bi-layer structure, which further comprises an effectively non-electroactive layer.

57. The actuator system as claimed in claim 56, wherein the non-electroactive layer comprises at least one of a metal layer, a soft reinforcing layer and an adhesion-preventing layer.

58. The actuator system as claimed in claim 53, wherein, in the substantially neutral state, the active electroactive polymer layer portion is substantially planar.

59. The actuator system as claimed in claim 53, wherein the active electroactive polymer layer portion, in the buckled state, is mechanically deformed relative to the neutral state, and in a plane perpendicular to the active electro-active polymer layer portion presents a curve having at least one point of inflection.

60. The actuator system as claimed in claim 53, wherein the electroactive polymer is a conducting polymer.

61. The actuator system as claimed in claim 54, wherein the electroactive polymer layer is formed on a substrate.

62. The actuator system as claimed in claim 61, wherein the substrate comprises first and second fixing portions, to which the fixed electro-active polymer layer portions are attached.

63. The actuator system as claimed in claim 61, wherein the active electroactive polymer layer portion extends over at least one of a recess, a slot and a hole in the substrate.

64. The actuator system as claimed in claim 53, wherein the first electroactive polymer layer at least partially covers at least one orifice, whereby said orifice is openable or closable by said shifting between said substantially neutral state and said buckled state.

65. The actuator system as claimed in claim 53, wherein a movable object is positioned such that a contact force between said movable object and the actuator device is achievable or increasable when the actuator device is shifted to its buckled state, whereby the movable object is displaceable relative to the actuator device.

66. The actuator system as claimed in claim 53,
further comprising a second electroactive polymer layer, having a second active electroactive polymer layer portion,
wherein the second active electroactive polymer layer portion is controllably shiftable between a substantially neutral state and a buckled state.

67. A pump device comprising at least one actuator system as claimed in claim 53.

68. An actuator array, comprising at least two actuator systems as claimed in claim 53.

69. A tactile display, comprising an actuator array as claimed in claim 68.

70. A sieve device, comprising an actuator system as claimed in claim 64, wherein said orifice is connected to a through hole.

71. A valve, comprising a channel having a channel wall, wherein at least a portion of said channel wall is provided with an actuator system as claimed in claim 53, arranged such that the actuator system, in the buckled state, reduces a cross sectional area of the channel.

72. A method for fabricating a buckling actuator, comprising:
providing a substrate presenting at least two areas which differ in terms of adhesion properties with respect to an electroactive polymer; and
providing a layer of said electroactive polymeron said areas, such that a first portion of the electroactive polymer layer is adhered to the substrate and a second portion of the electroactive polymer layer is movable relative to the substrate.

73. A method for fabricating a buckling actuator, comprising:
providing an electroactive polymer layer on a substrate; and
removing a portion of the substrate, while leaving a fixed active material portion adhering the electroactive polymer layer to the substrate.

74. The actuator system as claimed in claim 54, wherein the buckled state is achieved by an in-plane expansion of the first electroactive polymer layer.

75. The actuator system as claimed in claim 53, wherein the electroactive polymer layer forms part of a bi-layer structure, which further comprises an effectively non-electroactive layer.

76. The actuator system as claimed in claim 53, wherein the electroactive polymer layer is formed on a substrate.

77. The actuator system as claimed in claim 62, wherein the active electroactive polymer layer portion extends over at least one of a recess, a slot and a hole in the substrate.
